(19) United States
(12) Patent Application Publication
(10) Pub. No.: US 2024/0055036 A1
(43) Pub. Date: Feb. 15, 2024

(54) ELECTRIC CIRCUIT ASSEMBLY COMPRISING A FERROELECTRIC FIELD EFFECT TRANSISTOR, AND MEMORY CELL

(71) Applicant: Fraunhofer-Gesellschaft Zur Forderung Der Angewandten Forschung E.V., Munich (DE)

(72) Inventors: Thomas Kampfe, Dresden (DE); Nelli Laleni, Dresden (DE)

(73) Assignee: Fraunhofer-Gesellschaft Zur Forderung Der Angewandten Forschung E.V., Munich (DE)

(21) Appl. No.: 18/267,797

(22) PCT Filed: Dec. 14, 2021
(86) PCT No.: PCT/EP2021/085658

§ 371 Date: Jun. 16, 2023

(30) Foreign Application Priority Data
Dec. 16, 2020 (DE) 10 2020 216 060.0

(51) Int. Cl. G11C 11/22; G11C 15/04

(52) U.S. Cl. CPC G11C 11/223; G11C 11/2275; G11C 15/046

(57) ABSTRACT

An electric circuit assembly comprising a ferroelectric field effect transistor, an electric energy source, and a resistive element having a minimum electric resistance of 100 kOhm. The resistive element is electrically connected to a drain terminal of the ferroelectric field effect transistor, and the electric energy source is electrically connected to a gate terminal and a source terminal of the ferroelectric field effect transistor.

The present invention relates to an electric circuit assembly comprising a ferroelectric field effect transistor.

Certain applications, such as deep learning problems, utilize matrix-vector multiplications, which require access to large memory capacities, and, as a result, are generally used in processors having high energy consumption, and store the necessary weights and activations in dynamic random access memory (DRAM) technology. Since the total computing time and power consumption increasingly only depends on the speed or the energy consumption for accessing the memory, DRAM technology, however, is often slow and energy-intensive, the use of conventional technologies for such applications becomes more difficult or is entirely prevented.

Ferroelectric field effect transistors have a low latency period and are therefore an obvious choice for technical use. The publication US 2016/0027490 A1, for example, describes an assembly for erasing a memory from these transistors. The disadvantage here, however, is that threshold voltages and drain currents are often highly variable, and therefore cannot be set with sufficient precision.

It is therefore the object of the present invention to provide an electric assembly that avoids the aforementioned disadvantages, and by way of which a ferroelectric field effect transistor can thus be activated with greater precision.

This object is achieved according to the invention by an electric circuit assembly according to claim 1. Advantageous embodiments and refinements are described in the dependent claims.

An electric or electronic circuit assembly comprises a ferroelectric field effect transistor, an electric energy source, and a resistive element having a minimum electric resistance of 100 kOhm. The resistive element is electrically connected to a drain terminal of the ferroelectric field effect transistor, and the electric energy source is electrically connected to a gate terminal and a source terminal of the ferroelectric field effect transistor.

Due to the resistive element, the electric resistance of which clearly exceeds a pure line impedance and which is typically present as a separate component or circuit, low current variability is achieved, while, at the same time, the advantage of a high on/off ratio is preserved. The electric resistance of the resistive element is preferably 1 MOhm to 100 MOhm. A ferroelectric material here shall be understood to be in particular any material that has an electric dipole moment and changes the direction of spontaneous polarization when an external electric field is applied. As a result, it is also possible to compute logic operations, such as the multiply-accumulate operation (MAC operations), considerably more energy-efficiently and with high precision.

It may be provided that at least two ferroelectric field effect transistors are arranged in series with an analog-to-digital converter. As a result of this arrangement, in which at least one or exactly one resistive element is connected to the drain terminal of the ferroelectric field effect transistor and additionally an analog-to-digital converter is used, an assembly for logic circuits can be provided.

As an alternative or in addition, it may also be provided that the resistive element is composed of a current mirror and a current generator, that is, that a current mirror and a current generator form the resistive element.

Several ferroelectric field effect transistors can be arranged in a matrix arrangement or a crossbar array including at least two rows and at least two columns, wherein the gate terminals of all ferroelectric field effect transistors of a single row are electrically connected to a shared word line, all source outputs of the ferroelectric field effect transistors arranged in a single column are connected to a shared source line, and all drain terminals of the ferroelectric field effect transistors arranged in a single column are connected to a shared drain line. As a result of such matrix arrangements, programmable memory elements can be created, which due to the ferroelectric properties are very reliable.

Preferably, all drain lines of each column are connected to a dedicated analog-to-digital converter, and all source lines of each column are connected to the respective resistive element. This results in a grid-shaped arrangement, in which individual cells can be deliberately activated.

The ferroelectric field effect transistors can be programmed in different memory states. For forming a multi-bit content-addressable memory (MCAM), a positively programmed ferroelectric field effect transistor and a negatively programmed ferroelectric field effect transistor can be interconnected. The threshold value voltage of these two ferroelectric field effect transistors opens a search area.

A memory cell comprises an electric circuit assembly having the above-described properties. Instead of the described electric circuit assembly, it is also possible to use an electric circuit assembly in which the ferroelectric field effect transistor is replaced by a flash transistor, or a 1-transistor-1-resistor memory cell including a conventional transistor, that is, no ferroelectric field effect transistor, is used, which enable activation equivalent to the ferroelectric field effect transistors and can be used in a matrix arrangement as described. The resistance ratio of the resistive element to the low-resistance state of the memory cell should be at least 10. This memory cell typically has an on/off ratio of greater than 10².

In a method for programming an electric circuit assembly comprising a ferroelectric field effect transistor, an electric energy source, and a resistive element having a minimum electric resistance of 100 kOhm, wherein the resistive element is electrically connected to a drain terminal of the ferroelectric field effect transistor, and the electric energy source is electrically connected to a gate terminal and a source terminal of the ferroelectric field effect transistor, the ferroelectric field effect transistor is transferred into a state of logic one or logic zero by applying an electric voltage of a defined level to one of the terminals of the ferroelectric field effect transistor and connecting the further terminals to electric zero potential.

When several ferroelectric field effect transistors are arranged in a matrix arrangement, additionally only the ferroelectric field effect transistor to be programmed must be supplied with the electric voltage of a defined level to enable defined programming.

It may also be provided that, for programming, an electric voltage of preferably +/−4 V is applied to a single ferroelectric field effect transistor for typically 1 μs, wherein the source line and the drain line of the same row are supplied with a low voltage, preferably with a voltage of preferably +/−2.7 V, for typically 1 μs, and the word line of the same column is supplied with a lower voltage, preferably +/−1.3 V, for typically 1 μs. Deviating from this, it is possible to apply lower voltages with longer write times.

It may be provided that VT states of the ferroelectric field effect transistor are measured with the aid of the analog-to-digital converter and adapted by means of a further adaptation step using a further programming step.

The described method can typically be carried out by way of the described circuit assembly, or the described circuit assembly is designed to carry out the described method.

Exemplary embodiments of the invention are shown in the drawings and described hereafter based on FIGS. 1 to 23.

In the drawings:

FIG. 1 shows a schematic representation of an electric assembly comprising a field effect transistor;

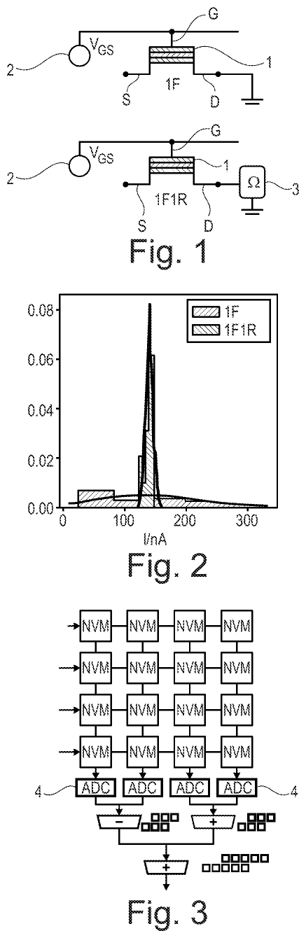

FIG. 2 shows a diagram in which the current variability is plotted against the current;

FIG. 3 shows a matrix configuration of several segments comprising ferroelectric field effect transistors;

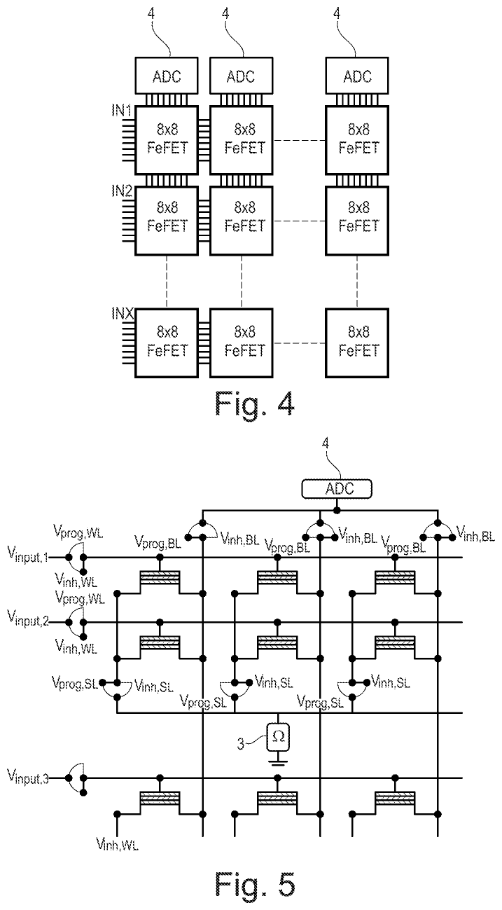

FIG. 4 shows a schematic view of several segments;

FIG. 5 shows a programming configuration of a segment that is connected to a single electric resistor;

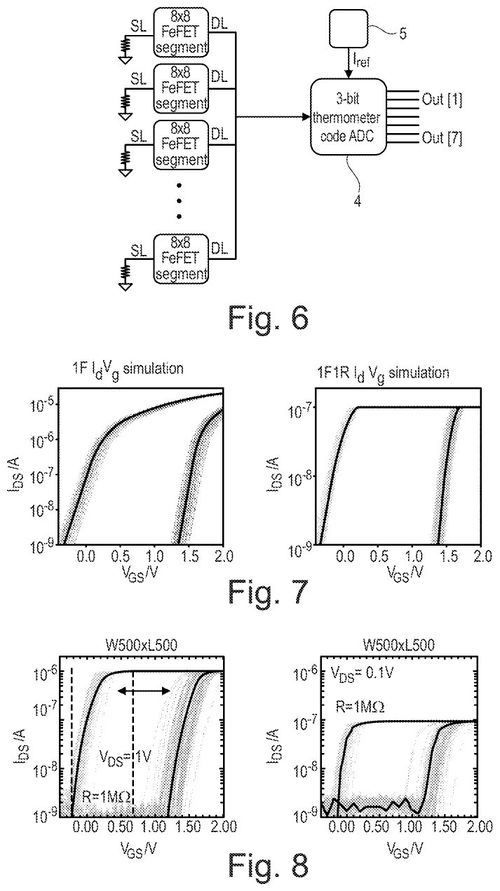

FIG. 6 shows a matrix arrangement including one column and a single analog-to-digital converter;

FIG. 7 shows diagrams regarding the current variability for different electric resistances;

FIG. 8 shows diagrams regarding the current variability for different electric voltages;

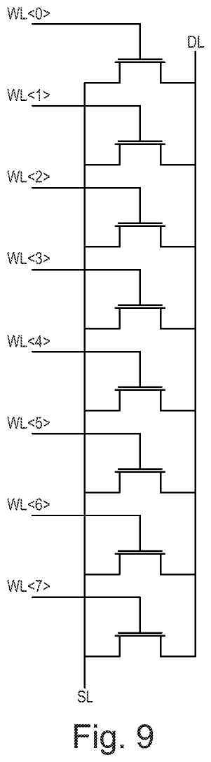

FIG. 9 shows a circuit diagram of a matrix arrangement of ferroelectric field effect transistors;

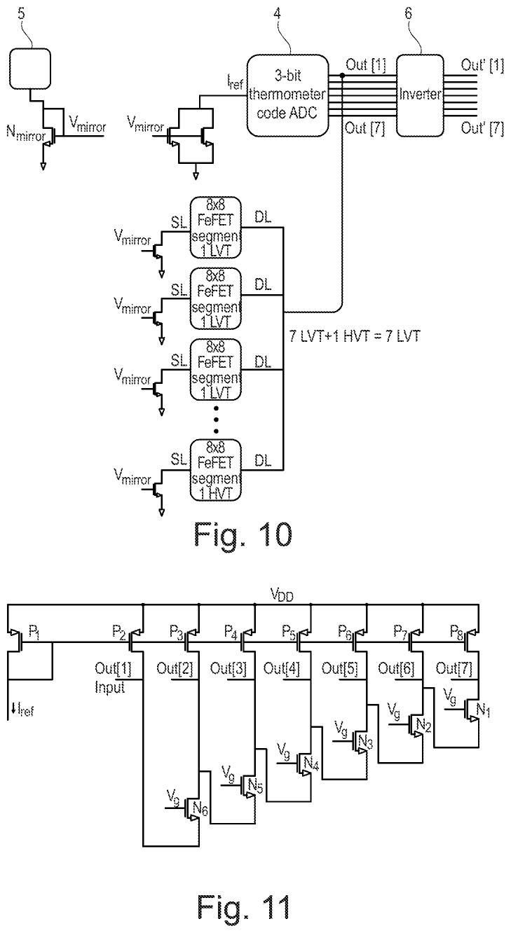

FIG. 10 shows a view of a further matrix arrangement corresponding to FIG. 6;

FIG. 11 shows a circuit diagram of one exemplary embodiment comprising one current generator for each segment;

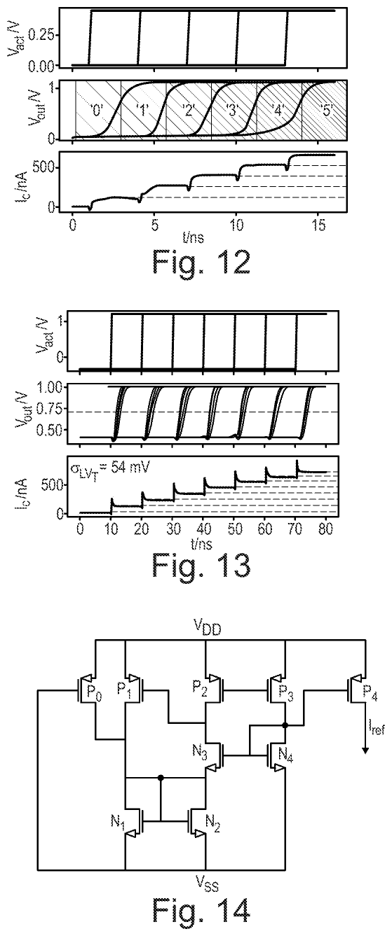

FIG. 12 shows a diagram of current and voltage curves at the analog-to-digital converter of the circuit shown in FIG. 11;

FIG. 13 shows a diagram of the response following the sequential activation of the transistors of the example shown in FIG. 11;

FIG. 14 shows a circuit diagram of a reference current generator;

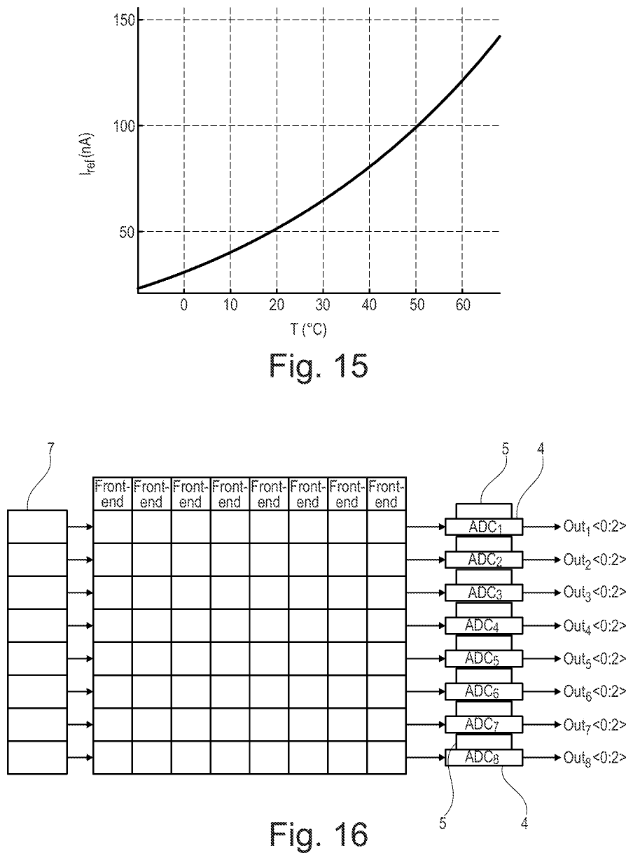

FIG. 15 shows a diagram of a temperature increase of the circuit shown in FIG. 14;

FIG. 16 shows a block diagram of a complete architecture;

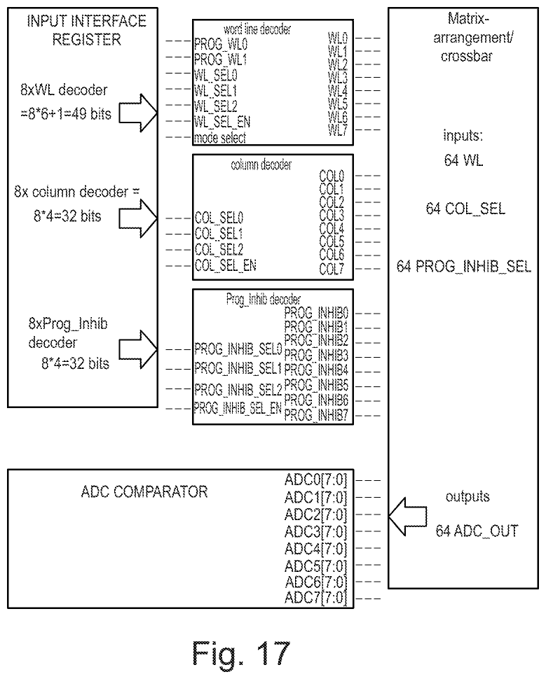

FIG. 17 shows a schematic view of saving input and output signals in registers;

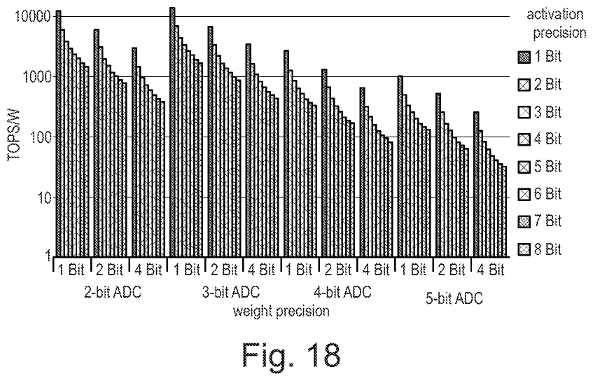

FIG. 18 shows an exemplary representation of the achievable TOPS/W at a given weight precision for the described architecture;

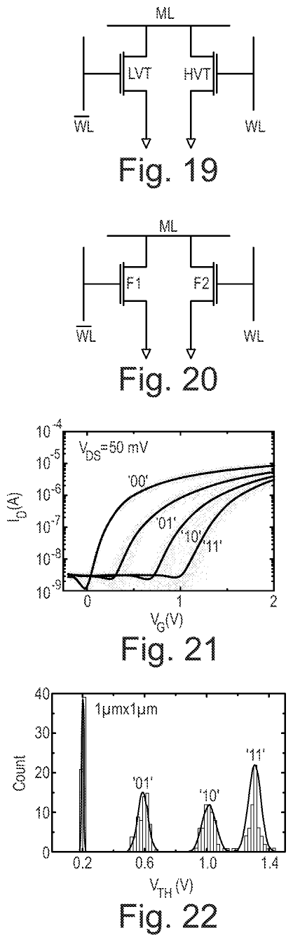

FIG. 19 shows a schematic representation of an MCAM cell;

FIG. 20 shows a schematic representation of a TCAM cell;

FIG. 21 shows a diagram of the drain current against the gate voltage of the MCAM cell;

FIG. 22 shows a diagram of the threshold voltage in four stages for the MCAM cell; and

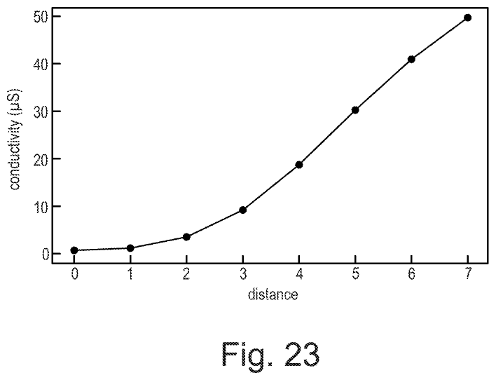

FIG. 23 shows a proposed distance function for the MCAM cell.

In the upper portion of the figure, FIG. 1 shows a schematic view of the design of a so-called “1F” configuration known from the prior art, in which a ferroelectric field effect transistor 1 is connected via the gate terminal G thereof to an electric energy source 2, that is, an electric current source or voltage source, and supplied by the same with an electric voltage Vis. A drain terminal D is connected to ground, that is, to electric zero potential.

In the lower portion of FIG. 1, a resistive element 3 having a minimum electric resistance of 100 kOhm is arranged between the drain terminal D and ground. Even though, this arrangement preserves the high on/off ratio, which is an inherent property of the ferroelectric field effect transistor 1, the variability with respect to the electric current is reduced. The resistive element 3 can be configured as a peripheral circuit, such as a 3-bit amplifier. As a result of the use of the ferroelectric field effect transistor 1 in this 1FeFET1R or 1F1R configuration, a read process can be carried out with low electric power and, due to the high on/off ratio, the transistor can be easily read out so that it can serve as a binary element for multiple-accumulate (MAC) operations. FIG. 2 shows the current variability against the electric current for both configurations.

FIG. 3 shows a matrix configuration or crossbar structure. Recurring features are denoted by identical reference numerals in this figure as well as the following figures. Several non-volatile memory (NVM) units are arranged in a grid shape in rows and columns. Each of the memory units comprises a ferroelectric field effect transistor 1. For example, a matrix made up of eight times eight ferroelectric field effect transistors 1 can be formed. Configurations comprising four times four or thirty-two times thirty-two ferroelectric field effect transistors, which form a coherent segment, are also possible. Moreover, the number of columns and the number of rows do not have to be identical, but can each be up to 1024. The gate terminals G of all transistors of a segment are connected to a shared word line WL, all source terminals S are connected to a shared source line SL, and all drain terminals D are connected to a shared drain line DL.

So as to program one of the memory units, only a single ferroelectric field effect transistor 1 per segment is selected and an electric voltage of +/−4 V is applied thereto (wherein the applied electric voltage at a word line WL can generally range between +/−1.5 V and +/−8 V, while all drain lines DL and all source lines SL are connected to ground, and a positive voltage is used for programming, and a negative voltage is used for erasing).

At the same time, an electric voltage of +/−2.7 V is applied to the source lines SL or drain lines DL of the same row of the programmed ferroelectric field effect transistor 1, and an electric voltage of +/−1.3 V is applied to the word lines WL of the same column, to prevent other ferroelectric field effect transistors from being programmed. After this programming or write process has ended, each ferroelectric field effect transistor is in a low VT (LVT) state, which corresponds to logic one, a high VT (HVT) state, which corresponds to logic zero, or an in-between VT state. FIG. 4 shows a schematic view of several segments, which are arranged in a matrix arrangement in several rows and several columns. Each of the rows is provided with dedicated input lines, while each of the columns is electrically connected to an analog-to-digital converter 4. FIG. 5 shows the switching transistors used for this purpose, which can switch between the different states, these being programming, inhibit (preventing programming) and read mode. Instead of ferroelectric field effect transistors 1, it is also possible to use a flash transistor or a 1-transistor-1-resistor memory cell in the assembly shown in FIG. 4 as well as in the further exemplary embodiments.

FIG. 5 shows a corresponding configuration of a segment for programming in a schematic view. The shown segment is electrically connected to a single resistive element 3 or a single electric resistor. During a computing or read operation, in each case only a single ferroelectric field effect transistor 1 is activated per segment, which means that the connecting transistors shown in FIG. 5 are in an open state, that is, electric voltage Vdd is typically applied, and is connected to the resistive element 3. Additionally, only a single resistive element 3 is used per segment.

An electric voltage of typically 0.5 V to 1.2 V is applied as input via the word line WL, wherein the source line SL is connected to the resistive element 3, and the read process is carried out by way of the drain line DL, which is connected to the analog-to-digital converter 4. In the illustrated exemplary embodiment, each column has eight segments, and each of the columns is connected to a single analog-to-digital converter 4. The respective analog-to-digital converters 4 digitize the input supplied by the electric current. As is likewise shown schematically in FIG. 6, a thermometer code analog-to-digital converter 4 can be used for this purpose, in which incoming logic signals on the drain line DL are added up. The example illustrated in FIG. 6 only shows an arrangement of eight segments in one column for the sake of simplicity. A reference current generator 5 is additionally connected to the thermometer code analog-to-digital converter 4, which provides a reference current, with respect to which low input current stages of the thermometer code analog-to-digital converter 4 are defined. In the exemplary embodiment shown in FIG. 5, a 3-bit analog-to-digital converter having eight stages can thus be provided. As was already described, all drain lines DL of the column are connected to the analog-to-digital converter 4 here, so that the result of each operation can be determined. Each of the source lines SL of the column is separately connected to the resistive element 3 since in each case only a single ferroelectric field effect transistor 1 of each segment is activated in the inference mode and can output a result. Each of the segments so-to-speak supplies a logic one or a logic zero, these values are accumulated along the drain line DL, and the analog-to-digital converter 4 digitizes these values for a digital representation of the MAC operation.

In the left diagram, FIG. 7 shows the current variability of a conventional ferroelectric field effect transistor 1 having a high on/off ratio in the LVT state. A high power level is required in the process to ensure high efficiency, since otherwise the current intensity fluctuates drastically, and the analog-to-digital converter 4 does not detect the correct value as output. Additionally, the electric current is very high, which would negatively influence the energy consumption of an arithmetic operation. The right diagram shows a corresponding curve of the drain-source current IDS against the gate-source voltage VGS for the circuit assembly shown in the lower portion of FIG. 1. As can be derived from the corresponding diagrams of FIG. 8, the circuit assembly shows no, or only very low, variability of the electric current within a range of 100 nA, in particular since a variability due to IR drop, stemming from the word line WL, is also suppressed due to the relatively large window of Vis. The left diagram of FIG. 8 shows corresponding curves in this regard for an electric voltage V_{DS} of 1 V, and the right diagram shows these for an electric voltage of V_{DS}=0.1 V.

FIG. 9, in turn, shows a schematic view of a matrix arrangement of several ferroelectric field effect transistors 1 in the form of a circuit diagram. Each of the illustrated ferroelectric field effect transistors 1 has a separate word line WL, but all source lines SL and drain lines DL are in each case connected to each other. During programming, all source lines SL and all drain lines DL are connected to ground, that is, electric zero potential. The word line WL of the ferroelectric field effect transistor 1 to be programmed has the voltage value V_{prog}. The remaining ferroelectric field effect transistors are supplied, as above, with a voltage of +/−1.3 V so as not to be programmed. As a result of the illustrated arrangement, again only the activated ferroelectric field effect transistor 1 will forward the electric current to the drain line DL, while the further field effect transistors practically do not contribute anything due to the high on/off ratio. This applies in particular to the ferroelectric field effect transistors in the LVT state, or low VT state, due to the use of an inhibit voltage adapted to the mean VT, which is typically 0 V to −0.3 V.

FIG. 10 shows a further exemplary embodiment corresponding to FIG. 6. In this exemplary embodiment, the first seven segments comprise an activated ferroelectric field effect transistor 1 in the LVT state, while the eighth segment comprises an activated ferroelectric field effect transistor 1 in the HVT state. Only the LVT state can thus contribute to the total electric current since the threshold voltage Vₜₕ of the transistor is very high in the HVT state, and no electric current can be supplied. The total current is thus seven LVT. The reference current generator 5 provides a stable direct current, that is, a direct current that is constant over the time, which is conducted over a current mirror and supplied as I_{ref} to the analog-to-digital converter 4. A multiplication process is carried out at the activated ferroelectric field effect transistors 1, an addition process is carried out along the drain line DL, and a digitization is carried out at the analog-to-digital converter 4. The analog-to-digital converter 4 receives the total current of all segments and converts this into a digital output signal. Finally, this output signal is inverted by the inverter 6 to render combining the output signals of all analog-to-digital converters 4 easier. So as to reduce the electric voltage V_{DS} between the gate terminal and the source terminal, additionally an n-type metal-oxide-semiconductor (NMOS) transistor or a p-type metal-oxide-semiconductor (PMOS) transistor can be used, instead of the electric resistor, and thus form the resistive element. This transistor acts as a mirror for the reference current generator 5 and provides a direct current of 100 nA to the ferroelectric field effect transistor 1, which in further exemplary embodiments, however, may also range between 100 pA and 10 μA. This results in a voltage VDS of 100 mV, which, however, may also range between 10 mV and 1 V.

In a further exemplary embodiment, the circuit diagram of which is shown in FIG. 11, a single current generator can be used per segment, which is connected to a column or a row of the segment, in each case as a function of an output voltage. Additionally, a single analog-to-digital converter 4 is used for each column to detect the output current of the activated ferroelectric field effect transistor 1. FIG. 10 shows a 3-bit thermometer code flash analog-to-digital converter 4, in which all outputs are set to “high” in the original state. The output “Out[1]” is connected to the arrays of ferroelectric field effect transistors 1 serving as the input. As soon as the electric current generated by the field effect transistors 1 is greater than the electric current of the first branch, the output “Out[1]” no longer meets the requirements and activates the second branch. As the electric current of the matrix arrangement rises, this operation is expanded to all branches. The PMOS transistors of the analog-to-digital converter 4 are designed in ascending order with respect to the width thereof, so as to similar current steps at the output, taking into consideration the squared ratio between the electric current and voltage for complementary metal-oxide semiconductor (CMOS) technology. This results in a linear representation of the added-up electric current along the bit line. In FIG. 12, the corresponding process is plotted with five stages at the analog-to-digital converter 4 against the time, while FIG. 12 shows the corresponding response with respect to the sequential activation of the ferroelectric field effect transistors 1 that are in the LVT state.

FIG. 14 shows a further circuit diagram of an exemplary embodiment in which conventional reference current generators use a current mirror and an additional electric resistor. The resistor is replaced by the transistor N2. So as to enable a stable flow of current, it is important to keep the transistor N2 below the saturation range thereof, which means that the transistor N1 is operated in saturation. The transistors N3 and N4 of the current mirrors are operated in weak inversion. The current generator shown in FIG. 13 operates in a metastable state, which means that only one starting circuit is required to reach the desired current value, which otherwise remains at 0 A. The transistor Po assumes this role, serving as a starting point for the entire circuit. FIG. 15 accordingly shows the temperature rise of the shown reference current generator with increasing reference current.

FIG. 16 shows a block diagram of a complete architecture, based on the above-described exemplary embodiments. In the illustrated exemplary embodiment of an architecture, eight times eight segments as well as accordingly eight analog-to-digital converters 4 and current generators 7 or electric energy sources 2, respectively, are used, so that two 4-bit weight MAC operations can be carried out per clock cycle (if 1024 analog-to-digital converters 4 were used, it would accordingly be 256 MAC operations). Each of the current generators 7 is connected to one column of the segments, which, in turn, as described, are each electrically connected to an analog-to-digital converter 4 for outputting a respective output signal “Outₓ”. A respective reference current generator 5 are connected to each of the analog-to-digital converters 4. Furthermore, it is possible to share the reference currents of the reference current generator 5 with further analog-to-digital converters 4 or to share these for several columns of segments, respectively.

As is customary, input and output signals can be stored in registers, as is shown by way of example in FIG. 17 for the case of eight times eight segments. The registers control the decoder for the word line WL, the column decoder, and the decoder “Prog_Inhib”. The output signal of the analog-to-digital converters 4 can be stored in registers for further computation, wherein, however, other terminals can also be connected to the output of the analog-to-digital converter 4.

Simulations of various configurations of the analog-to-digital converter 4 having differing precision (2-bit, 3-bit, 4-bit, 5-bit), which is connected to the described matrix structure, show that the best performance is achieved for a 3-bit analog-to-digital converter 4, having a chip size of 2 μm² and a maximum total power of 700 nW, which is operated at 1 GS/s. The average power consumption in this case is 200 nW, which is typically achieved with a 100 nA reference current and corresponding digitization step, and a supply voltage of 1 V. This can be reduced to 200 pW for lower reference currents up to 100 pA. The described architecture can be operated in the range of 1-bit to 8-bit activation precision (in the case of eight segments), and 1-bit, 2-bit and 4-bit weight precision (typically 1024 bit for 1024 analog-to-digital converters 4). FIG. 18 accordingly shows a diagram of the weight precision, including the associated TOPS/W (tera-operations per second/W).

The described topology can be used in various configurations to produce a so-called multi-bit content-addressable memory (MCAM) cell or a ternary content-addressable memory (TCAM) cell. Each of these cells is in each case composed of two ferroelectric field effect transistors 1 and can be easily implemented since one of the two ferroelectric field effect transistors 1 is programmed in the LVT state, and the other in the HVT state. The MCAM cell is shown in FIG. 19, and the TCAM cell is shown in FIG. 20.

The input voltages are applied following an XNOR operation of the input voltage. ML is therefore set to logic one for different word lines WL and will remain in this state when the input is set to zero. The analog-to-digital converter 4 will register the current level of the cells. As is shown in FIG. 19, the two ferroelectric field effect transistors 1 are in different states and have different Vₜₕ in the MCAM cell. The corresponding Id-V G curve is shown in FIG. 21 in the form of a diagram, as is the distribution of the threshold voltages Vₜₕ in 4 stages with 60 units in FIG. 22 for a write pulse width of 200 ns. Finally, FIG. 23 shows the distance function, that is, the conductivity over the distance, of a single MCAM cell. To ensure that the analog-to-digital converter 4 follows the same curve, the variables of the transistors P2-P8 shown in FIG. 11 differ and likewise follow this curve. In the illustrated case, the reference current generator is operated without a mirror transistor so that the electric voltage of this configuration can supply the memory cells directly.

Features of the different embodiments only disclosed in the exemplary embodiments can be claimed in combination with one another and individually.

The project that resulted in the present application was funded by the ECSEL Joint Undertaking (JU) according to grant agreement no. 826655. The JU receives funding from the HORIZON 2020 research and innovation program of the European Union, and from Belgium, France, Germany, the Netherlands, and Switzerland.

1-13. (canceled)

14. An electric circuit assembly, comprising a ferroelectric field effect transistor, an electric energy source, and a resistive element having a minimum electric resistance of 100 kOhm, wherein the resistive element is electrically connected to a drain terminal of the ferroelectric field effect transistor, and the electric energy source is electrically connected to a gate terminal and a source terminal of the ferroelectric field effect transistor.

15. The electric circuit assembly according to claim 14, wherein the electric resistance of the resistive element is 1 MOhm to 100 MOhm.

16. The electric circuit assembly according to claim 15, wherein the resistive element is composed of a current mirror and a current generator.

17. The electric circuit assembly according to claim 14, wherein the at least two ferroelectric field effect transistors are arranged in series with an analog-to-digital converter.

18. The electric circuit assembly according to claim 14, wherein a plurality of ferroelectric field effect transistors are arranged in a matrix arrangement including at least two rows and at least two columns, the gate terminals of all ferroelectric field effect transistors of a single row being electrically connected to a shared word line, all source outputs of the ferroelectric field effect transistors arranged in a single column being connected to a shared source line, and all drain terminals of the ferroelectric field effect transistors arranged in a single column being connected to a shared drain line.

19. The electric circuit assembly according to claim 18, wherein that all drain lines of each column are connected to a dedicated analog-to-digital converter, and all source lines of each column are connected to the respective resistive element.

20. A memory cell, comprising an electric circuit assembly according to claim 14, in which the ferroelectric field effect transistor is replaced by a flash transistor.

21. The memory cell according to claim 20, having an on/off ratio of greater than 102.

22. The electric circuit assembly according to claim 14, wherein that, for forming a multi-bit content-addressable memory, a positively programmed ferroelectric field effect transistor and a negatively programmed ferroelectric field effect transistor are interconnected.

23. A method for programming an electric circuit assembly comprising a ferroelectric field effect transistor, an electric energy source, and a resistive element having a minimum electric resistance of 100 kOhm, the resistive element being electrically connected to a drain terminal of the ferroelectric field effect transistor, and the electric energy source being electrically connected to the gate terminal and a source terminal of the ferroelectric field effect transistor, wherein the ferroelectric field effect transistor is transferred into a state of logic one or logic zero by applying an electric voltage of a defined level to one of the terminals of the ferroelectric field effect transistor and connecting the further terminals to electric zero potential.

24. The method according to claim 23, wherein that, when a plurality of ferroelectric field effect transistors are arranged in a matrix arrangement, only the ferroelectric field effect transistor to be programmed is supplied with the electric voltage of a defined level.

25. The method according to claim 23, wherein that, for programming, an electric voltage of +/−4 V is applied to a single ferroelectric field effect transistor, the source line and the drain line of the same row being supplied with a low voltage, preferably with a voltage of +/−2.7 V, and the word line of the same column being supplied with a lower voltage, preferably +/−1.3 V.

26. The method according to claim 23, wherein that VT states of the ferroelectric field effect transistor are measured with the aid of an analog-to-digital converter and adapted by means of a further adaptation step using a further programming step.
